(19) United States
(12) Patent Application Publication
(10) Pub. No.: US 2016/0268290 A1
(43) Pub. Date: Sep. 15, 2016

(54) METHOD OF MANUFACTURING SEMICONDUCTOR DEVICE AND SEMICONDUCTOR DEVICE

(71) Applicant: Kabushiki Kaisha Toshiba, Minato-ku (JP)

(72) Inventors: Yosuke MATSUNAGA, Yokkaichi (JP); Takuji KUNIYA, Yokkaichi (JP)

(73) Assignee: Kabushiki Kaisha Toshiba, Minato-ku (JP)

(21) Appl. No.: 14/741,621

(22) Filed: Jun. 17, 2015

Related U.S. Application Data
(60) Provisional application No. 62/131,483, filed on Mar. 11, 2015.

(51) Int. Cl. H01L 27/115

(52) U.S. Cl. CPC H01L 27/11582

(57) ABSTRACT

In a method of manufacturing a semiconductor device of an embodiment, first and second mask patterns are formed on a stacked body formed on a semiconductor substrate. Then, a first step-like pattern and a first dummy pattern are formed from the stacked body. When the second mask pattern becomes smaller than a predetermined size, a resist is applied, and a third mask pattern using the resist is formed. Then, a second step-like pattern and a second dummy pattern are formed from the stacked body.

### CROSS-REFERENCE TO RELATED APPLICATIONS

This application is based upon and claims the benefit of priority from U.S. Provisional Application No. 62/131,483, filed on Mar. 11, 2015; the entire contents of which are incorporated herein by reference.

### FIELD

Embodiments described herein relate generally to a method of manufacturing a semiconductor device, and a semiconductor device.

### BACKGROUND

As one of semiconductor devices, there is a three-dimensional device in which a plurality of memory cell patterns is stacked. In such a three-dimensional device, a plurality of layers of memory cell patterns is stacked. Further, wiring is drawn out to a periphery of a region where the memory cell patterns are formed. The wiring is formed in a step-like manner.

In step formation process of forming a step-like wiring pattern, a resist pattern is formed on a wiring stacked film in which wiring layers are stacked. Then, etching of the wiring stacked film using the resist pattern as a mask, and slimming of the resist pattern are repeated a plurality of times. Further, when the etching of the resist pattern is advanced, the resist pattern is removed, and a new resist pattern is formed on the wiring stacked film. Then, the etching and the slimming are repeated a plurality of times. Accordingly, the wiring stacked film becomes a step-like stacked pattern.

However, in the step formation process, a step difference becomes large between an upper layer step and a lower layer step, as the number of steps becomes large. Therefore, when a resist is applied on the step-like stacked pattern in formation of a new resist pattern, the resist flows into a lower layer side of the step-like stacked pattern, and thus it is difficult to secure a desired resist film thickness. When the desired resist film thickness cannot be secured, the resist pattern (mask) disappears during the etching of the wiring stacked film, and it becomes difficult to form the step-like stacked pattern. Therefore, it is desired to apply the resist to the step-like stacked pattern with a desired resist film thickness.

### BRIEF DESCRIPTION OF THE DRAWINGS

FIGS. 1A to 1I are diagrams for describing a processing procedure of forming a step-like pattern according to an embodiment;

FIGS. 2A and 2B are diagrams illustrating an arrangement example of a dummy pattern;

FIG. 3 is a diagram for describing a resist film applied on a step difference region with a dummy pattern;

FIG. 4 is a diagram for describing a resist film applied on a step difference region without a dummy pattern;

FIG. 5 is a diagram for describing a resist film of when a dummy mask pattern disappears before completion of a step-like pattern; and

FIG. 6 is a diagram illustrating a cross sectional configuration of a semiconductor device according to an embodiment.

### DETAILED DESCRIPTION

In general, according to the present embodiment, a method of manufacturing a semiconductor device is provided. In the method of manufacturing a semiconductor device, a stacked body in which a plurality of films is stacked is formed on a semiconductor substrate. Further, a first mask pattern is formed on the stacked body, and a second mask pattern is formed on the stacked body. Then, first processing including processing of etching the stacked body, and processing of slimming the second mask pattern is repeated. Accordingly, a first step-like pattern in which a lower side than the second mask pattern is remained, and a first dummy pattern in which a lower side than the first mask pattern is remained are formed from the stacked body. Then, when the second mask pattern becomes smaller than a predetermined size, the second mask pattern is removed. Following that, a resist is applied on the semiconductor substrate. Further, a third mask pattern using the resist is formed on the stacked body. Then, second processing including the processing of etching the stacked body, and the processing of slimming the second mask pattern is repeated. Accordingly, a second step-like pattern in which a lower side than the first step-like pattern is remained, and a second dummy pattern in which a lower side than the first dummy pattern is remained are formed from the stacked body.

Exemplary embodiments of a method of manufacturing a semiconductor device and a semiconductor device will be described in detail with reference to the accompanying drawings. The present invention is not limited to the following embodiments. Further, in the present embodiment, a step-like stacked pattern is referred to as step-like pattern. In a semiconductor device, a plurality of memory cell layers is connected to respective wiring layers of a step-like pattern, and the step-like pattern is connected to a wiring plug.

### Embodiment

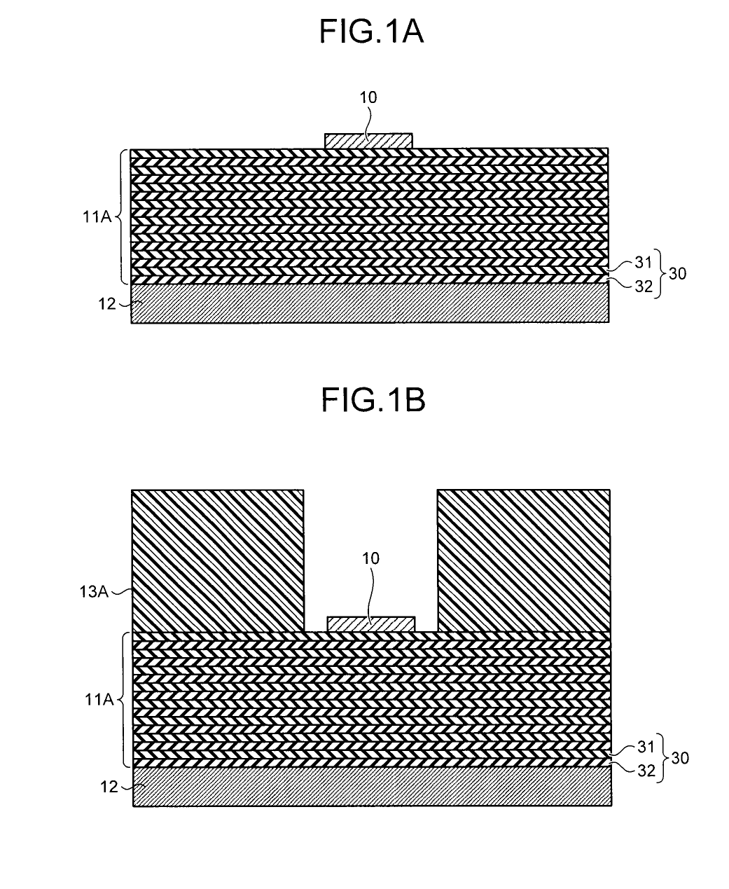

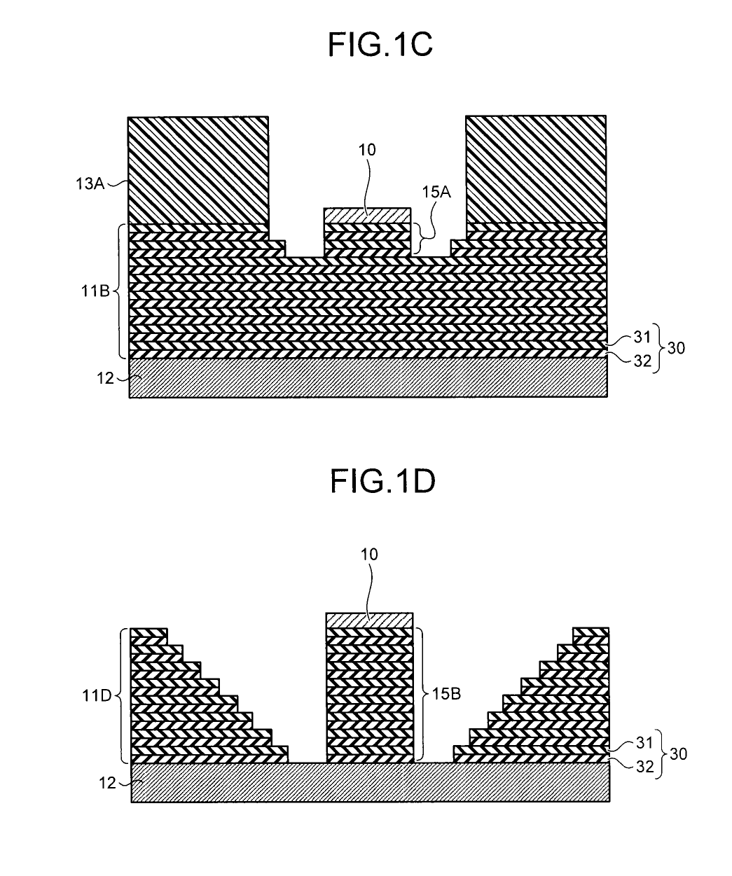

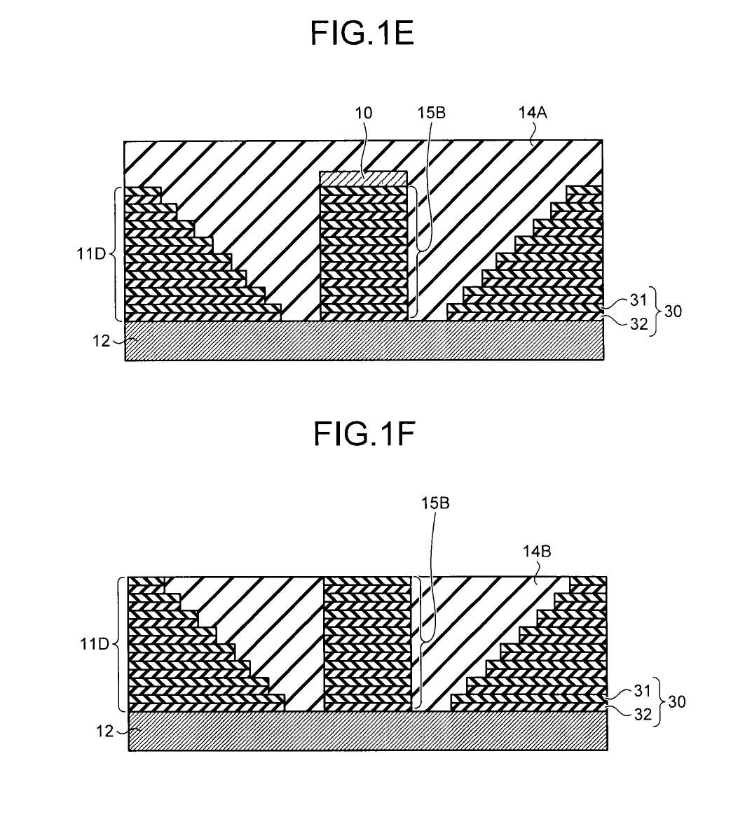

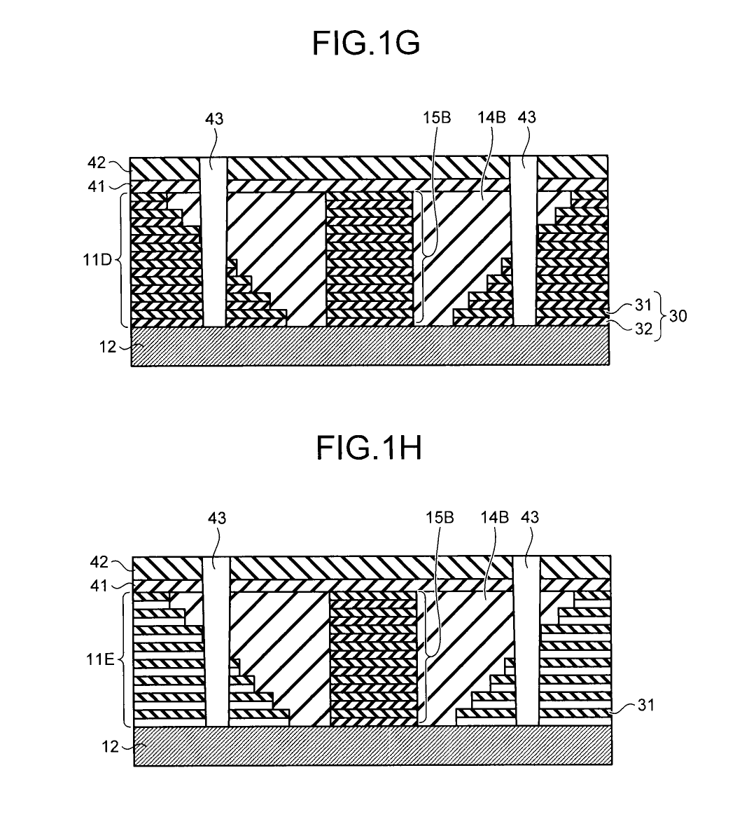

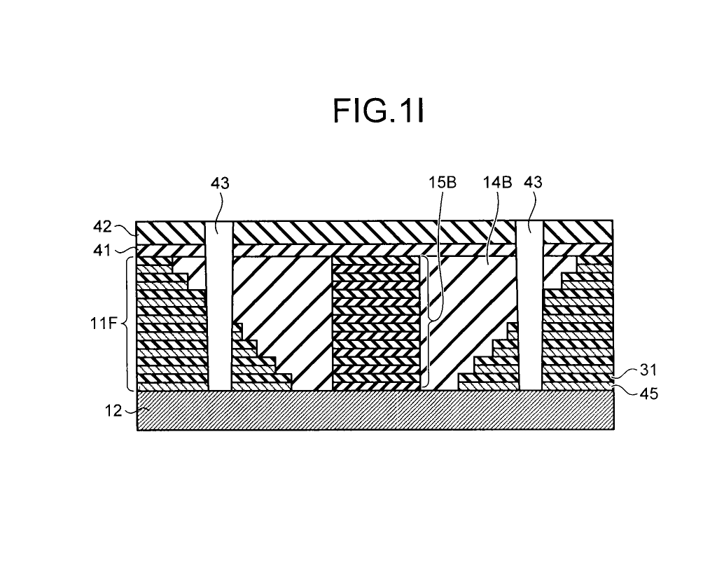

FIGS. 1A to 1I are diagrams for describing a processing procedure of forming a step-like pattern according to an embodiment. In the present embodiment, a method of manufacturing a semiconductor device (three-dimensional device) in which a plurality of memory cell patterns is stacked will be described. FIGS. 1A to 1I illustrate cross sectional views of a substrate (semiconductor substrate) 12 such as a wafer.

In a semiconductor device including memory cell patterns in a stacked structure, typically, a string is formed in a vertical direction to a substrate surface. Therefore, wiring is drawn out to a periphery of a region where memory cells are formed. Then, the wiring is formed on each of the step-like layers.

Such a semiconductor device includes a memory cell pattern in which a plurality of memory layers is stacked, and a step-like pattern formed of wiring layers. In a step formation process of forming the step-like pattern, as illustrated in FIG. 1A, a plurality of insulating layers 30 made of silicon oxide 31/silicon nitride 32 (SiO/SiN) is stacked on the substrate 12 in an alternate manner, so that a stacked body 11A is formed. The silicon nitride 32 of the insulating layers 30 is a layer to be replaced with a wiring layer in subsequent processing.

Further, in the present embodiment, a dummy mask pattern (first mask pattern) 10 to be used in formation of a dummy pattern is formed on the stacked body 11A. The dummy mask pattern 10 is formed in a region of the stacked body 11A, where the step-like pattern and the memory cells are not formed. When viewing the stacked body 11A from an upper surface side, there are a region where the step-like pattern and the memory cells are formed, and a region where the step-like pattern and the memory cells are not formed, on the stacked body 11A. Between the regions, the dummy mask pattern 10 is formed on a part of the region where the step-like pattern and the memory cells are not formed.

The dummy mask pattern 10 is configured from a member with a lower etching rate than a resist pattern 13A described below, when the stacked body 11A is etched. The dummy mask pattern 10 is, for example, amorphous silicon or polysilicon.

After the dummy mask pattern 10 is formed, as illustrated in FIG. 1B, the thick resist pattern (first mask pattern) 13A with a predetermined open region is formed on the stacked body 11A. The open region here is a region where the memory cells, the step-like pattern, and the like are not formed. The open region exposes the dummy mask pattern 10 and its peripheral portion. In this way, the resist pattern 13A is formed such that the dummy mask pattern 10 and its both side regions are open. In other words, the resist pattern 13A is formed on the region where the memory cells and the step-like pattern are formed. Note that, since the resist pattern 13A is etched a plurality of times, the dummy mask pattern 10 have a film thickness that is remained after the plurality of times (for example, ten times) of etching.

Next, the insulating layer 30 in a region corresponding to the open region of the resist pattern 13A is etched by one layer by a reactive ion etching (RIE) method. At this time, the insulating layers 30 at a lower side than the dummy mask pattern 10 are not etching. In other words, one layer of the insulating layer 30 is etched using the resist pattern 13A and the dummy mask pattern 10 as a mask.

Following that, slimming processing (degeneration processing) of reducing a plane size of the resist pattern 13A is performed. This slimming processing is performed by isotropic plasma etching processing. In the slimming processing, the resist pattern 13A is reduced by a predetermined size in a direction parallel to an upper surface of the substrate 12 (horizontal direction). Then, the plane size of the resist pattern 13A is reduced (side surfaces retreat by the predetermined size), so that a part of a surface of an uppermost insulating layer 30 is newly exposed.

Next, the exposed insulating layers 30 are etched by one layer using the slimmed resist pattern 13A and the dummy mask pattern 10, as a mask, by the RIE method. Accordingly, the insulating layer 30 (the second insulating layer 30 from the top) in the place removed by the prior etching is removed, and the insulating layer 30 (the first insulating layer 30 from the top) next to the second insulating layer 30, which is exposed from the resist pattern 13A, is removed.

In other words, a region exposed by the slimming of the resist pattern 13A, of the first insulating layer 30 from the top, is etched. Further, a region exposed by the etching of the first insulating layer 30, of the second insulating layer 30 from the top, is etched.

Then, the processing from the slimming of the resist pattern 13A to the etching of one layer of the insulating layer 30 is repeated. Accordingly, the step-like pattern in which the steps are formed in order from an upper layer portion side is formed one by one in the stacked body 11A. The insulating layers 30 at a lower layer side than the dummy mask pattern 10 are not etched.

FIG. 10 illustrates a state of the stacked body after the two insulating layers 30 are etched, as a stacked body 11B. Further, a pattern at a lower layer side than the dummy mask pattern 10 after the two insulating layers 30 are etched is illustrated as a dummy pattern 15A. Further, the resist pattern 13A after the two insulating layers 30 are etched is illustrated.

The film thickness of the resist pattern 13A becomes thinner as the etching of the insulating layers 30 is advanced. At a point of time when a predetermined number of insulating layers 30 is etched, the resist pattern 13A becomes thinner than an allowable film thickness. At this point of time, the resist pattern 13A thinner than the allowable film thickness is removed from the stacked body 11B. Then, a new resist pattern 13B (not illustrated) is formed on the stacked body 11B. In other words, a resist pattern 13B for forming next and subsequent step-like patterns is formed.

The processing described in FIG. 1B and the processing described in FIG. 1C are repeated for the substrate 12. That is, processing (a) and processing (b) below are repeated once to a plurality of times.

(a) Processing of forming the thick resist pattern 13B with a predetermined region open, on the substrate 12
(b) Processing of etching the stacked body 11B using the resist pattern 13B as a mask

Further, in the processing (b), processing (c) and processing (d) below are repeated a plurality of times.

(c) Processing of etching the exposed insulating layer 30, of the stacked body 11B, by one layer
(d) Processing of slimming the resist pattern 13B

Accordingly, as illustrated in FIG. 1D, a stacked body 11D that is a step-like pattern, and a dummy pattern 15B are formed on the substrate 12. The dummy pattern 15B is a pattern at a lower layer side than the dummy mask pattern 10 after the uppermost to the lowermost insulating layers 30 are etched. In other words, the dummy pattern 15B is a pattern after the step-like pattern is completed by the etching of the stacked body 11A. Therefore, an upper surface of the dummy pattern 15B has the same height as an upper surface of the stacked body 11D.

After the stacked body 11D that is a step-like pattern is formed, as illustrated in FIG. 1E, an interlayer insulating film 14A is stacked on the stacked body 11D and the dummy mask pattern 10. Accordingly, the interlayer insulating film 14A is embedded in gaps between the stacked body 11D and the dummy pattern 15B. In this way, the stacked body 11D, the dummy mask pattern 10, and the dummy pattern 15B are covered with the interlayer insulating film 14A. The interlayer insulating film 14A here is, for example, a silicon oxide film such as tetraethyl orthosilicate (TEOS).

After the interlayer insulating film 14A is stacked, etching back or dry etching by chemical mechanical polishing (CMP) is performed from the interlayer insulating film 14A. Accordingly, as illustrated in FIG. 1F, the interlayer insulating film 14A is flattened to become an interlayer insulating film 14B, and the dummy mask pattern 10 is removed. As a result, the first insulating layer 30 from the top of the stacked body 11D, and the first insulating layer 30 from the top of the dummy pattern 15B are exposed.

After the interlayer insulating film 14B is formed, a memory string MS described below is two-dimensionally formed on the substrate 12 in an approximately vertical manner. The memory string MS has a configuration in which a plurality of transistors is connected in series.

Note that the memory strings MS have a configuration including a plurality of transistors in a height direction of the semiconductor film. These transistors include a gate dielectric film formed on a side surface of a columnar semiconductor film, and a gate electrode film formed on the gate dielectric film. In the semiconductor device, a plurality of memory strings MS is arranged on the substrate 12 in an approximately vertical manner.

Following that, as illustrated in FIG. 1G, cap layers 41 and 42 are stacked on the upper surface of the substrate 12. Accordingly, the stacked body 11D, the dummy pattern 15B, and the interlayer insulating film 14B are covered with the cap layer 41. Further, the cap layer 41 is covered with the cap layer 42. The cap layers 41 and 42 are, for example, insulating films.

After the cap layers 41 and 42 are stacked, a slit (groove pattern) 43 that divides the region where the memory cells are formed (cell region) is formed. The slit 43 divides the cell region, a step region, a region near the region where the dummy pattern 15B is arranged, and the like. The slit 43 is a groove pattern with a large aspect ratio, for example. The slit 43 is a groove pattern serving as a separation portion (not illustrated) that electrically separates the cell region and the like when a conductive film and an insulating film are embedded in a subsequent process.

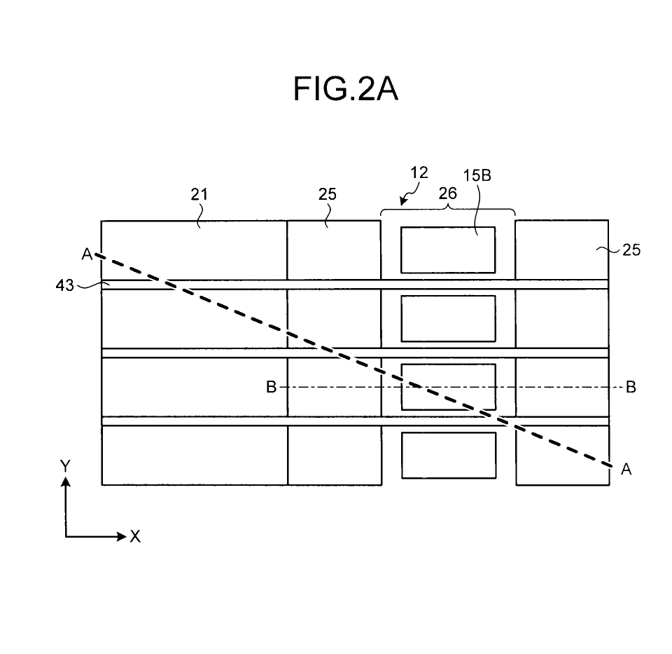

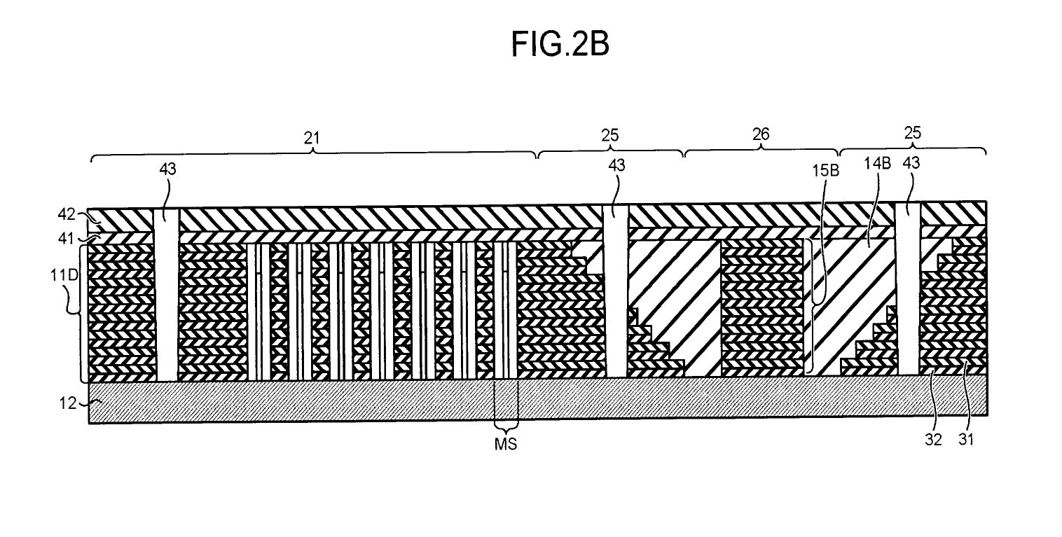

Here, arrangement position of the dummy pattern 15B will be described. FIGS. 2A and 2B are diagrams illustrating an arrangement example of a dummy pattern. FIGS. 2A and 2B illustrate cross sectional views of the substrate 12 after the dummy pattern 15B is formed.

FIG. 2A illustrates a top view of the substrate 12 such as wafer. FIG. 2B illustrates a cross sectional view of when the substrate 12 of FIG. 2A is cut in the AA line. Note that FIG. 1A to FIG. 1G, and FIGS. 1H and 11 described below illustrate cross sectional views of when the substrate 12 of FIG. 2A is cut in the BB line.

A cell region 21, a step region 25, and a peripheral region 26 are included in the region on the substrate 12. The peripheral region 26 is arranged in a region that is neither cell region 21 nor step region 25. The cell region 21 is a region in which the memory cell patterns are formed. A plurality of memory cell patterns is stacked on the cell region 21.

The step region 25 is a region in which the insulating layers 30 are processed in a step-like manner. The respective insulating layers 30 of the stacked body 11D are connected to the layers (memory cell pattern layers) where the memory cell patterns are formed. For example, when first to N-th (N is a natural number) memory cell pattern layers are formed, first to N-th insulating layers 30 are stacked as the stacked body 11D. Then, the M-th (M is 1 to N) memory cell pattern layer and the M-th insulating layer 30 are connected.

One end portion of the cell region 21 in a longitudinal direction (X direction) is the step region 25. One end portion of the step region 25 in the X direction is linked to the cell region 21. Further, the other end portion of the step region 25 in the X direction is adjacent to the peripheral region 26. Then, one end portion of the peripheral region 26 in the X direction is adjacent to the step region 25, and the other end portion is adjacent to the step region 25. In other words, the peripheral region 26 is sandwiched by the step regions 25.

A plurality of sets of memory region made of the cell region 21 and the step region 25 is arranged on the substrate 12. Then, the adjacent memory regions are separated through the slit 43. For example, a first memory region is configured from a first cell region 21 and a first step region 25. Further, a second memory region is configured from a second cell region 21 and a second step region 25. Then, the slit 43 is arranged such that the first cell region 21 and the second cell region 21 are separated, and the first step region 25 and the second step region 25 are electrically divided.

The slit 43 passes between the cell regions 21 and between the step regions 25, and passes through the peripheral region 26. The peripheral region 26 is a region where all of the insulating layers 30 are etched and the substrate 12 is exposed when the step-like stacked body 11D is formed.

As described above, the cell region 21, the step region 25, and the peripheral region 26 are divided by the slit 43 that is a groove pattern.

The dummy pattern 15B of the present embodiment is arranged in a position not overlapping with the slit 43 in the peripheral region 26. For example, the dummy pattern 15B is arranged in a position between the slit 43 and the slit 43, and not being in contact with the slits 43. In other words, the slits 43 of the present embodiment are formed in positions not coming across the dummy pattern 15B.

Further, as illustrated in FIG. 2B, the memory string MS is formed in the stacked body 11D on the substrate 12. The memory string MS is two-dimensionally formed in the stacked body 11D in an approximately vertical manner. The memory string MS has a configuration in which a plurality of transistors is connected in series.

After the slits 43 are formed, as illustrated in FIG. 1H, the silicon nitrides 32 in the stacked body 11D are removed by the wet etching or the like. At this time, the silicon nitrides 32 in the dummy pattern 15B are covered with the cap layers 41 and 42, and the interlayer insulating film 14B, and are thus not removed by the wet etching. The stacked body 11D becomes a stacked body 11E by the removal of the silicon nitrides 32.

Following that, as illustrated in FIG. 1I, electrode films (metal films) 45 such as tungsten are embedded in places in the stacked body 11D, where the silicon nitrides 32 have been removed. Accordingly, the stacked body 11E becomes a stacked body 11F in which the electrode films 45 are embedded.

Further, a mask pattern (not illustrated) is formed on the cap layers 41 and 42. The mask pattern has openings in positions corresponding to portions of respective steps of the step-like pattern. These openings are a pattern for allowing contact holes to be formed. Following that, the interlayer insulating film 14B and the insulating layer 30 (silicon oxide 31) immediately under the interlayer insulating film 14B are selectively etched by the RIE method using the mask pattern as a mask.

Accordingly, a plurality of contact holes (not illustrated) is formed in the silicon oxide 31 and the interlayer insulating film 14B of the insulating layer 30. The plurality of contact holes has mutually different depths from an upper surface of the interlayer insulating film 14B. The contact holes penetrate the interlayer insulating film 14B and the silicon oxide 31, and reach the electrode films 45 of corresponding steps, respectively. Following that, contact electrodes (wiring plugs) are embedded in the contact holes.

In the processing of forming a step-like pattern, after the resist pattern 13A that becomes thinner than the allowable film thickness is removed from the stacked body 11B, a new resist pattern 13B is formed on the stacked body 11B. In this case, in forming the resist pattern 13B, a resist film that is a base of the resist pattern 13B is applied on the substrate 12.

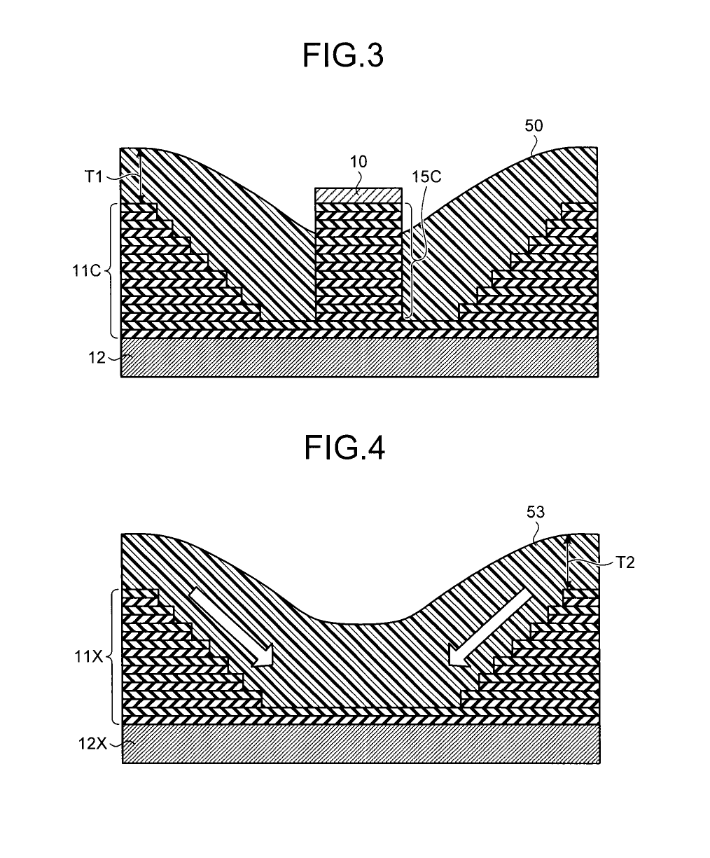

Here, processing of applying a resist film that is a base of the resist pattern will be described. FIG. 3 is a diagram for describing a resist film applied on a step difference region with a dummy pattern. FIG. 3 illustrates a cross section of the substrate 12 on which a dummy pattern 15C is arranged.

In the processing of forming a step-like pattern, when the resist pattern 13A becomes thinner than the allowable film thickness, the resist pattern 13A is removed from the stacked body 11B. Following that, a resist 50 serving as a base of the new resist pattern 13B is formed on a stacked body 11C.

In a middle of the formation of a step-like pattern, a step difference is caused between an upper layer portion side and a lower layer portion side of the stacked body 11C. When the resist 50 is applied on a step difference region with the step difference, the resist 50 flows into the lower layer side of the step-like pattern.

In the present embodiment, the dummy pattern 15C is formed in the region where the step-like pattern is not formed. As described above, the dummy pattern 15C is arranged on the substrate 12, and thus the amount of the resist 50 flowing into the lower layer side of the step-like pattern can be suppressed. Therefore, the resist 50 with a desired film thickness T1 can be easily applied on the substrate 12. In addition, the film thickness T1 of the resist 50 becomes stable, and thus the film thickness T1 can be made thick.

Further, in the present embodiment, if the dummy mask pattern 10 is formed, the dummy mask pattern 10 can be used in a plurality of steps of etching. Therefore, it is not necessary to pattern the dummy pattern in each step of the step-like pattern.

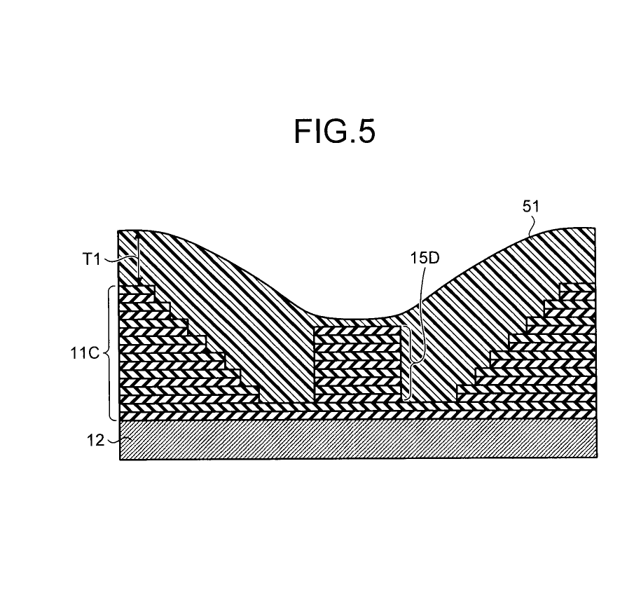

FIG. 4 is a diagram for describing a resist film applied on a step difference region without a dummy pattern. FIG. 4 illustrates a cross section of a substrate 12X on which a dummy pattern is not arranged. FIG. 4 illustrates a state in which a step difference is caused between an upper layer portion side and a lower layer portion side of a stacked body 11X in the middle of formation of a step-like pattern.

The step difference becomes larger as the number of steps of the step-like pattern becomes larger. Therefore, when a resist 53 is applied on the step difference region without a dummy pattern, the resist 53 flows into the lower layer side of the step-like pattern. In this case, if there is no dummy pattern, a large amount of the resist 53 flows into the lower layer side of the step-like pattern. Therefore, a film thickness T2 of the resist 53 becomes unstable. Therefore, it is difficult to secure the desired resist film thickness in the case of no dummy pattern.

Note that the dummy mask pattern 10 may disappear by etching before completion of the stacked body 11D that is the step-like pattern. FIG. 5 is a diagram for describing a resist film of when a dummy mask pattern disappears before completion of a step-like pattern. FIG. 5 illustrates a cross section of the substrate 12 from which the dummy mask pattern 10 has disappeared.

FIG. 5 illustrates a resist film applied on a step difference region without a dummy pattern. FIG. 5 illustrates a resist 51 of when the dummy mask pattern 10 has disappeared in the middle of formation of the step-like pattern (at the time of completion of the stacked body 11C).

In the processing of forming a step-like pattern, when the resist pattern becomes thinner than the allowable film thickness, the resist pattern is removed from the stacked body 11B. Following that, the resist 51 serving as a base of a new resist pattern is formed on the stacked body 11C.

In forming the stacked body 11C, the etching of the insulating layer 30 is repeated from the dummy mask pattern 10, and thus the film thickness of the dummy mask pattern 10 becomes thin. Then, there is a case in which the dummy mask pattern 10 may disappear due to the etching of the insulating layer 30 before the completion of the stacked body 11D that is a step-like pattern.

Even in such a case, the dummy pattern 15D at a lower layer side than the dummy mask pattern 10 is remained on the substrate 12. Therefore, when the resist 51 is applied from the stacked body 11C, the amount of the resist 51 flowing into the lower layer side of the step-like pattern can be suppressed. Therefore, the resist 51 with a desired film thickness T1 can be easily applied on the substrate 12. In addition, the film thickness T1 of the resist 51 becomes stable, and thus the film thickness T1 can be made thick.

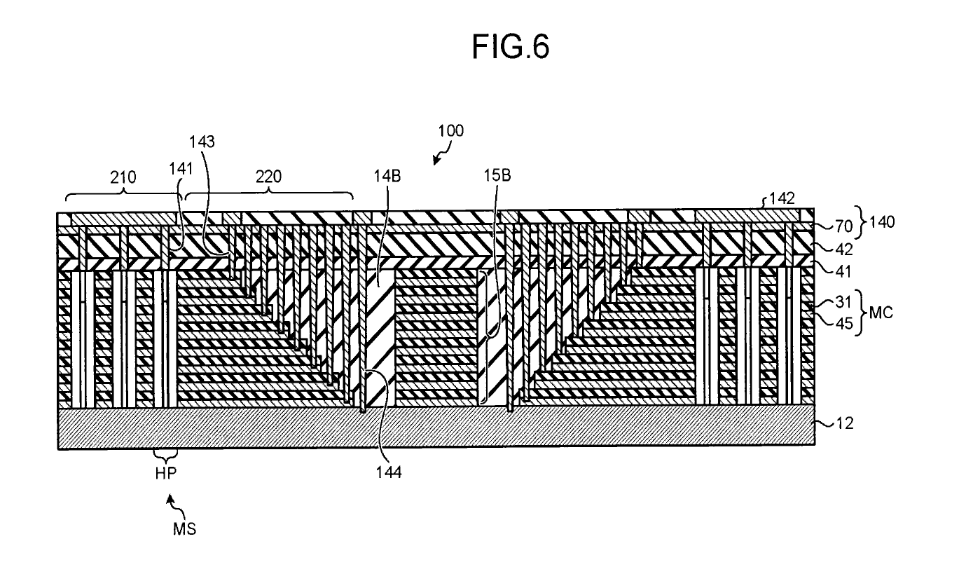

FIG. 6 is a diagram illustrating a cross sectional configuration of a semiconductor device according to an embodiment. FIG. 6 schematically illustrates an example of a cross sectional configuration of a memory cell portion and a word line contact portion in a semiconductor device (non-volatile semiconductor storage device) 100 according to an embodiment in a direction perpendicular to a bit line direction. A memory cell portion 210 is formed in the cell region 21, and the word line contact portion 220 is formed in the step region 25.

In the word line contact portion 220, the memory string MS is two-dimensionally arranged on the substrate 12 in an approximately vertical manner. The memory string MS has a configuration in which a plurality of transistor is connected in series. The memory string MS includes a pillar portion HP and the electrode films 45. The electrode films 45 are formed such that metal films such as tungsten are formed in positions from which the silicon nitrides 32 are removed.

The pillar portion HP has a structure in which ONO film that configures a hollow pillar tunnel insulating film, a charge storage film, and an inter-electrode insulating film is stacked on an external peripheral surface of a hollow pillar semiconductor film. The hollow pillar semiconductor film serves as a channel of the transistors that configure the memory string MS. As the semiconductor film, a polysilicon film that is annealed amorphous silicon can be used, for example. A plurality of the electrode films 45 is arranged in a height direction of the pillar portion HP through the silicon oxides 31. The silicon oxide 31 here functions as a spacer film.

The silicon oxide 31 of the dummy pattern 15B, and the silicon oxide 31 in the memory cell portion 210 and the word line contact portion 220 are formed in positions of the same height. Further, the silicon oxide 31 of the dummy pattern 15B, and the silicon oxide 31 in the memory cell portion 210 and the word line contact portion 220 are formed of the same member having the same film thickness.

Note that an inside of the hollow pillar semiconductor film is filled with an embedding insulating film such as a silicon oxide film up to a predetermined height, and the inside is embedded with a cap film such as a P-type amorphous silicon film on and above the predetermined height.

Upper and lower end transistors, of the transistor line connected in series in the height direction, are selection transistors. For example, a source-side selection transistor is arranged at the lower side, and a drain-side selection transistor is arranged at the upper side. One or more memory cell transistors MC are formed between these two selection transistors at predetermined intervals. In this example, the structure of the selection transistors is the same as that of the memory cell transistors.

The memory cell portion 210 and the word line contact portion 220 are partitioned with a separation portion extending in a word line direction. The separation portion has a configuration in which a conductive film and an insulating film such as a silicon oxide film are embedded in the slit 43 that penetrates a stacked body in the thickness direction, the stacked body being formed such that the electrode films 45 and the silicon oxides 31 that are spacer films are stacked.

The transistors of the same height in a region sandwiched by the separation portions are connected with the same electrode film 45. For example, the source-side selection transistor in the region sandwiched by the separation portions is connected with the electrode film 45 of the lowermost layer. The drain-side selection transistor in the region sandwiched by the separation portions is connected with the electrode film 45 of the uppermost layer. These electrode films 45 serve as selection gate lines.

Further, the memory cell transistors MC of the same height in the region sandwiched by the separation portions are connected with the respective electrode films 45. The electrode films 45 connected among the memory cell transistors MC serve as word lines.

The electrode films 45 extending from the memory cell portion 210 are stacked and arranged in the word line contact portion 220. The electrode films 45 configure a step-like configuration such that the lower electrode films 45 are exposed. The word line contact portion 220 also has a structure in which the silicon oxide 31 is arranged between adjacent upper and lower electrode films.

A wiring formed layer 140 is formed on the memory strings MS of the memory cell portion 210 and the interlayer insulating film 14B of the word line contact portion 220. The wiring formed layer 140 has a structure in which a patterned wiring layer 142 is arranged between interlayer insulating films 70 stacked in the height direction.

Contacts 141 connecting upper ends of the memory strings MS and the wiring layer 142 are provided in the cap layers 41 and 42. Further, contacts 143 are provided in the cap layers 41 and 42, and the interlayer insulating film 14B so as to connect the electrode films 45 of the respective steps of the word line contact portion 220 and the wiring layer 142.

Further, a peripheral circuit and the like are arranged on the substrate 12. Elements such as a transistor (not illustrated) are arranged on the peripheral circuit. FIG. 6 illustrates a state in which a contact 144 is connected to a source region of the peripheral circuit transistor.

Note that, in the present embodiment, a case in which the step-like pattern is a pattern used as a wiring layer and the like has been described. However, the step-like pattern may be any pattern.

As described above, according to the embodiment, the dummy pattern 15B is formed in the recessed region where the memory cells and the step-like pattern are not formed. Therefore, the amount of the resist flowing into the lower layer side of the step-like pattern can be suppressed. Therefore, the resist can be applied to the step-like stacked pattern with a desired resist film thickness.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming, on a semiconductor substrate, a stacked body in which a plurality of films is stacked;
forming a first mask pattern on the stacked body;
forming a second mask pattern on the stacked body;
repeating first processing including processing of etching the stacked body, and processing of slimming the second mask pattern;
forming a first step-like pattern in which a lower side than the second mask pattern is remained, and a first dummy pattern in which a lower side than the first mask pattern is remained, from the stacked body;
removing the second mask pattern when the second mask pattern becomes smaller than a predetermined size;
applying a resist on the semiconductor substrate;
forming a third mask pattern using the resist on the stacked body;
repeating second processing including processing of etching the stacked body, and processing of slimming the third mask pattern; and
forming a second step-like pattern in which a lower side than the first step-like pattern is remained, and a second dummy pattern in which a lower side than the first dummy pattern is remained, from the stacked body.

2. The method of manufacturing a semiconductor device according to claim 1, wherein
the stacked body is a body in which a first insulating layer used in formation of an electrode film, and a second insulating layer used in formation of a spacer film arranged between the electrode films are alternately stacked.

3. The method of manufacturing a semiconductor device according to claim 1, wherein
the first mask pattern is a dummy mask pattern formed in a region in which the stacked body is not used in formation of a memory cell and the first and second step-like patterns, the region being of an upper surface region of the stacked body.

4. The method of manufacturing a semiconductor device according to claim 1, wherein
the second mask pattern is a first resist pattern formed in a first region on the electrode film.

5. The method of manufacturing a semiconductor device according to claim 1, wherein
the third mask pattern is a second resist pattern formed in a second region on the electrode film.

6. The method of manufacturing a semiconductor device according to claim 2, wherein
the electrode films are formed in positions of the first insulating layers included in the first and second step-like patterns.

7. The method of manufacturing a semiconductor device according to claim 6, wherein
the first insulating layer is a silicon nitride.

8. The method of manufacturing a semiconductor device according to claim 6, wherein
the second insulating layer is a silicon oxide.

9. The method of manufacturing a semiconductor device according to claim 3, wherein
the dummy mask pattern is amorphous silicon or polysilicon.

10. The method of manufacturing a semiconductor device according to claim 1, comprising:
forming an interlayer insulating film on the semiconductor substrate after the second step-like pattern is formed;
etching back and flattening the dummy mask pattern and the interlayer insulating film when the dummy mask pattern is remained; and
etching back and flattening the interlayer insulating film when the dummy mask pattern is not remained.

11. The method of manufacturing a semiconductor device according to claim 1, wherein
there is a plurality of cell regions in which the memory cells are arranged, on one layer,
the cell regions are divided by a groove pattern, and
the first and second dummy patterns are formed in a region not overlapping with the groove pattern.

12. The method of manufacturing a semiconductor device according to claim 2, comprising:
forming a cap layer on the first dummy pattern;
performing wet etching from the cap layer;
making the first insulating layers remain included in the first and second dummy patterns; and
removing the first insulating layers included in the first and second step-like patterns.

13. The method of manufacturing a semiconductor device according to claim 12, wherein
a metal film is formed in a region from which the first insulating layer is removed and becomes the electrode film.

14. The method of manufacturing a semiconductor device according to claim 1, wherein
the first mask pattern of when the etching to the stacked body is started has a film thickness that is remained after the second mask pattern is etched a plurality of times.

15. A semiconductor device comprising:
memory cells arranged on a semiconductor substrate in a three-dimensional manner;
electrode films formed in a step-like manner and connected to the memory cells; and
a dummy pattern having a predetermined height and arranged in a region where the electrode films are not formed.

16. The semiconductor device according to claim 15, wherein
the dummy pattern includes a first insulating layer and a second insulating layer,
a third insulating layer is formed between the electrode film formed on a first layer of the step-like electrode films, and the electrode film formed on a second layer of the step-like electrode films, and
the second insulating layer and the third insulating layer are formed of a same member having a same film thickness.

17. The semiconductor device according to claim 16, wherein
the second insulating layer and the third insulating layer are arranged in positions of a same height.

18. The semiconductor device according to claim 16, wherein
the first insulating layer is a silicon nitride.

19. The semiconductor device according to claim 16, wherein
the second insulating layer is a silicon oxide.

20. The semiconductor device according to claim 15, wherein
the dummy pattern includes a first insulating layer and a second insulating layer,
a fourth insulating layer is arranged in a region where the memory cells are arranged, and
the second insulating layer and the fourth insulating layer are formed of a same member having a same film thickness.
